(19) United States
(12) Patent Application Publication
(10) Pub. No.: US 2016/0099355 A1
(43) Pub. Date: Apr. 7, 2016

(54) NON-VOLATILE MEMORY DEVICES WITH THIN-FILM AND MONO-CRYSTALLINE SILICON TRANSISTORS

(71) Applicant: Schiltron Corporation, Mountain View, CA (US)

(72) Inventor: Andrew J. Walker, Mountain View, CA (US)

(73) Assignee: Schiltron Corporation

(21) Appl. No.: 14/705,794

(22) Filed: May 6, 2015

Related U.S. Application Data
(60) Provisional application No. 62/060,115, filed on Oct. 6, 2014.

(51) Int. Cl. H01L 29/786; H01L 29/16; H01L 29/423; H01L 27/115; H01L 29/49

(52) U.S. Cl. CPC H01L 29/78645; H01L 27/11524; H01L 27/11529; H01L 27/11551; H01L 29/4908; H01L 29/42372; H01L 29/16

(57) ABSTRACT

A non-volatile memory device combines thin-film transistor-based memory cells with bulk mono-crystalline silicon transistors, which can more efficiently drive bit lines for fast sensing of the stored data in the thin-film memory cells.

### CROSS-REFERENCE TO RELATED APPLICATIONS

The present application is related to and claims priority of U.S. provisional patent application (“Copending Provisional application”), Ser. No. 62/060,115, entitled “Non-Volatile Memory Devices with Thin-Film and Mono-Crystalline Silicon Transistors,” filed on Oct. 6, 2014. The Copending Provisional patent application is hereby incorporated herein by reference in its entirety.

### BACKGROUND OF THE INVENTION

1. Field of the Invention

The present invention relates to non-volatile memory designs. In particular, the present invention relates to thin-film transistor-based nonvolatile memory devices that include bulk mono-crystalline silicon transistors.

2. Discussion of the Related Art

The typical thin-film transistor has a much lower electrical current-driving capability than a similarly sized transistor formed in the mono-crystalline bulk of a silicon wafer because of the disordered structure in the thin-film transistor's channel. The disordered structure results in a lower mobility in the charge carriers. The total current-driving capability is even lesser in a series-connected string of such thin-film transistors, such as typical in NAND-type non-volatile memory devices.

The advantages of the so-called dual-gate series string of nonvolatile thin-film transistors have been disclosed, for example, in the article, “Sub-50-nm Dual-Gate Thin-Film Transistors for Monolithic 3-D Flash” (the “Walker Article”), by A. J. Walker, published in the IEEE Transactions on Electron Devices, vol. 56, November 2009, pp. 2703-10. The Walker Article discloses the ability to read the state of a non-volatile memory cell in the series string, without disturbing the states of the other memory cells in the series string. Dual-gate memory structures are described, for example, in U.S. Pat. Nos. 7,612,411, 7,410,845, 7,339,821, 7,459,755, 7,777,268 and 7,777,269. The current expected out of a series string of thin-film memory cells may be less than 100 nA.

In a memory array, the string current is sensed on bit lines that are of fairly high capacitance. For example, for a NAND-type “flash” memory device, a series string of nonvolatile memory cells formed in the mono-crystalline bulk of the silicon wafer may be expected to deliver a current that is typically 200-300 nA to drive high capacitance bit lines that are typically 2-4 pF. As the time required to sense the data on the bit lines is substantial, a large “read latency” results. “Read latency” refers to the time required for an initial access of any desired storage location in the series string. The physics of this phenomenon is described, for example, in “Nonvolatile Memories: NOR vs. NAND Architectures” by L. Crippa et al., in Chapter 2 of the book “Memories in Wireless Systems,” edited by R. Micheloni et al., published by Springer-Verlag Berlin Heidelberg, 2008. In thin-film transistor-based non-volatile memory devices, the read latency is expected to be exacerbated relative to series-strings in a mono-crystalline NAND memory device, as the total current tends to be smaller in the thin-film transistor-based memory cells.

Accordingly, a thin-film non-volatile memory structure with an improved read latency is desired, preferably taking advantage of the 3-dimensional stacking in such a memory structure.

### SUMMARY

According to one embodiment of the present invention, a non-volatile memory device combines thin-film transistor-based memory cells with bulk mono-crystalline silicon transistors, which can more efficiently drive bit lines for fast sensing of the stored data in the thin-film memory cells.

In one embodiment, a thin-film transistor-based non-volatile memory structure is separated by a dielectric layer (i.e., an electrically insulating layer) from the mono-crystalline bulk silicon underneath. The electrical terminals of the thin-film transistors are not formed in the mono-crystalline bulk silicon. In such a configuration, the mono-crystalline bulk silicon both underneath and in the vicinity of the thin-film transistor-based nonvolatile memory structure can therefore be used to make transistors that have better current handling capabilities than the thin-film transistors. These mono-crystalline silicon transistors can be used, therefore, to drive electrical signals onto the high capacitance bit lines. Consequently, sense circuitry formed by mono-crystalline silicon transistors can be incorporated into a memory array of thin-film transistor-based cells by forming the sense circuitry underneath the thin-film transistors. In this configuration, the thin-film transistors need control only nodes that have relatively little capacitance and which are located relatively close. Such an arrangement compares favorably with sense circuitry in a conventional mono-crystalline NAND-type flash memory structure that needs to be placed at the edges of the memory array.

The present invention is better understood upon consideration of the detailed description below in conjunction with the accompanying drawings.

### BRIEF DESCRIPTION OF THE DRAWINGS

FIG. 1 is a block diagram illustrating non-volatile memory array 100 provided according to one embodiment of the present invention.

FIG. 2 is a block diagram illustrating amplifiers 202-1 to 202-4 each receiving output signals from two memory strings, according to this another embodiment of the present invention.

FIG. 3 shows SRAM cell 300 configured for use as an amplifier for thin-film transistor-based non-volatile memory strings, in accordance with one embodiment of the present invention.

FIG. 4 shows SRAM cell 400 configured for use as an amplifier for thin-film transistor-based non-volatile memory strings, in accordance with one embodiment of the present invention.

FIG. 5 shows sense amplifier 500 configured as an amplifier for thin-film transistor-based non-volatile memory strings, in accordance with one embodiment of the present invention.

FIG. 6 shows local reference comparator 600 configured for use as an amplifier for thin-film transistor-based non-volatile memory strings, in accordance with one embodiment of the present invention.

FIG. 7 is a layout of a dual-gate thin-film transistor nonvolatile string having eight word lines and two select transistors.

FIG. 8 illustrates in cross section dual-gate strings 801 of thin-film transistor-based nonvolatile memory integrated with mono-crystalline silicon bulk transistors 802, according to one embodiment of the present invention.

FIGS. 9-12 show various three-dimensional views of an implementation of the embodiment illustrated in FIG. 8.

FIG. 13 illustrates in cross section dual-gate strings 1301 and 1302 of thin-film transistor-based nonvolatile memory array 1300, fabricated on two different thin-film structures, integrated with mono-crystalline silicon bulk transistors 1307, according to one embodiment of the present invention.

FIGS. 14-17 show various three-dimensional views of an implementation of the embodiment illustrated in FIG. 13.

### DETAILED DESCRIPTION OF THE PREFERRED EMBODIMENTS

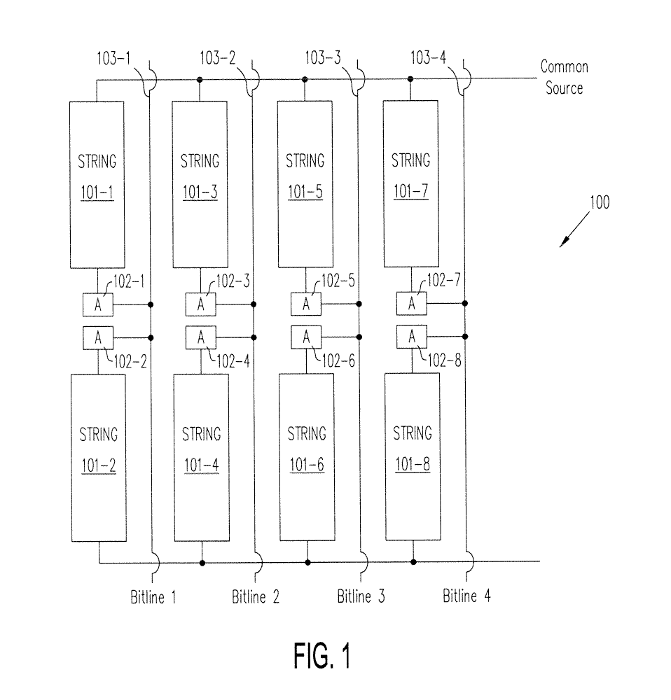

FIG. 1 is a block diagram illustrating non-volatile memory array 100 provided according to one embodiment of the present invention. The non-volatile memory array may include dual-gate thin-film devices or transistors as non-volatile storage devices. Each dual-gate device may include a floating gate as one of the gate elements in the dual-gate device. In some embodiments, floating gates may be used as both of the gate elements in the dual-gate device. The floating gate may be implemented by a small-dimension thin film conductor (e.g., less than 20 nanometers thick or on each side). The thin-film conductor may be formed out of any suitable material, such as titanium nitride (TiN), tantalum nitride (TaN), doped polysilicon, or any combination thereof. Alternatively, the floating gate may be provided in a dielectric layer embedded with conductor nanodots, also known as nanocrystals.

As shown in FIG. 1, thin-film transistor-based nonvolatile memory strings 101-1 to 101-8 are respectively connected to amplifiers 102-1 to 102-8 of memory array 100. Amplifiers 102-1 to 102-8 are each placed in the portion of the mono-crystalline bulk silicon that is local to the thin-film transistors. Each storage cell in memory strings 101-1 to 101-8 may store data in the form of electrical charge in a thin film (e.g., a silicon nitride film), or alternatively in a floating conductor gate. Solely for illustrative purposes, memory array 100 is shown in FIG. 1 with only eight memory strings. A typical memory array of the present invention, however, may have any number of memory strings. In this detailed description, the term “string” refers to a group of thin-film transistor memory cells that are serially connected by their source or drain regions. For the purpose of this detailed description, “bulk” silicon may also refer to the thin mono-crystalline silicon layer on a silicon-on-insulator (SOI) wafer. Also, solely for the purpose of illustration, FIG. 1 shows amplifiers 102-1 to 102-8 being spaced laterally away from the nonvolatile strings 101-1 to 101-8. In practice, some or all parts of each of amplifiers 102-1 to 102-8 may be placed underneath non-volatile strings 101-1 to 101-8. Typically, string selects lines are also present, but not expressly shown in FIG. 1 for simplicity of illustration. Amplifiers 102-1 to 102-8 drive the output signals of the corresponding memory strings onto corresponding bit lines 103-1 to 103-4 of memory array 100. Typically, the distance between each amplifier and its associated thin-film transistor string is shorter than the bit line driven by the amplifier.

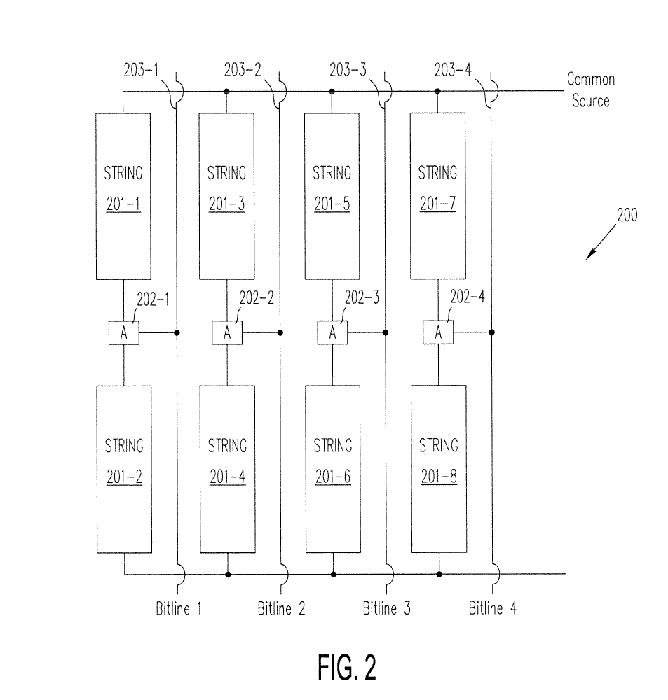

According to another embodiment of the present invention, amplifiers 102-1 to 102-8 may receive output signals from more than one string. Such an arrangement allows more space to be allocated to the layout of each amplifier and allows differential comparisons (e.g., comparing between an output signal of a selected string and an output signal of a string in an adjacent block that is not selected). FIG. 2 is a block diagram illustrating amplifiers 202-1 to 202-4 each receiving output signals from two memory strings, according to this embodiment of the present invention. As shown in FIG. 2, non-volatile thin-film transistor-based memory strings 201-1 to 201-8 of non-volatile memory array 200 provide their output signals to local amplifiers 202-1 to 202-4. Amplifiers 202-1 to 202-4 drive bit lines 203-1 to 203-4, respectively. Amplifiers 202-1 to 202-4 each receive input signals from more than one memory string. Amplifiers 202-1 to 202-4 each include an output stage in which at least one transistor is formed in the mono-crystalline bulk of the silicon wafer. The memory strings associated with each amplifier in the configuration of FIG. 2 may be selected by the same or different select or word lines.

Those skilled in the art would understand that any technique that is applicable to an amplifier driving a bit line of a non-volatile memory string may be used. For example, each amplifier may be configured as a sense amplifier that receives a reference signal (e.g., a reference voltage signal) for comparison with an output signal of an associated memory string. Memory strings associated with each amplifier in the configuration of FIG. 2 may be selected by the same or different select or word lines.

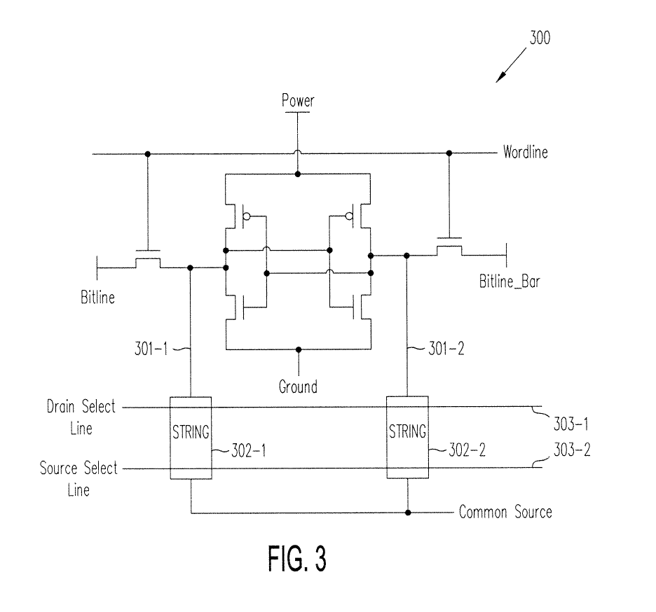

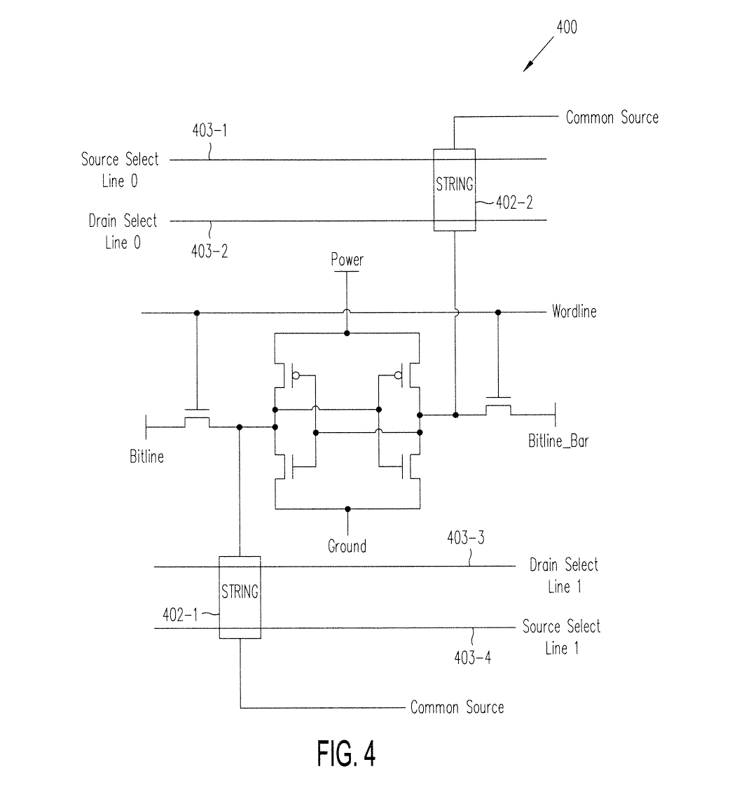

One applicable amplifier suitable for use as an amplifier of the present invention includes a static random access memory (SRAM) cell. FIG. 3 shows SRAM cell 300 which receives at terminal 301-1 an output signal from memory string 302-1, and receives at terminal 301-2 an output signal from adjacent string 302-2. In this example, the stored values of the corresponding memory cells in memory strings 302-1 and 302-2 are of complementary digital states (i.e., in this example, two memory cells are used to store a single digital value). Memory strings 302-1 and 302-2 are both selected by word lines 303-1 and 303-2. In contrast, FIG. 4 shows SRAM cell 400 receiving output signals from memory strings 402-1 and 402-2 that are not selected by the same select or word lines (i.e., memory string 402-1 is selected by select or word lines 403-3 and 403-4, while memory string 402-2 is selected by select or word lines 403-1 and 403-2). In the configuration of FIG. 4, the contents of the memory strings associated with each amplifier may be independent of each other. In the example of FIG. 4, where the memory string contents are independent, when the content of a memory cell in one memory string is read, the select or word lines of the corresponding memory cell in the other memory string are not activated. The transistors of SRAM cells 300 and 400 of FIGS. 3 and 4 may be formed in the bulk mono-crystalline silicon, while their associated memory strings may be formed out of thin-film transistors in the layers provided over the bulk mono-crystalline silicon.

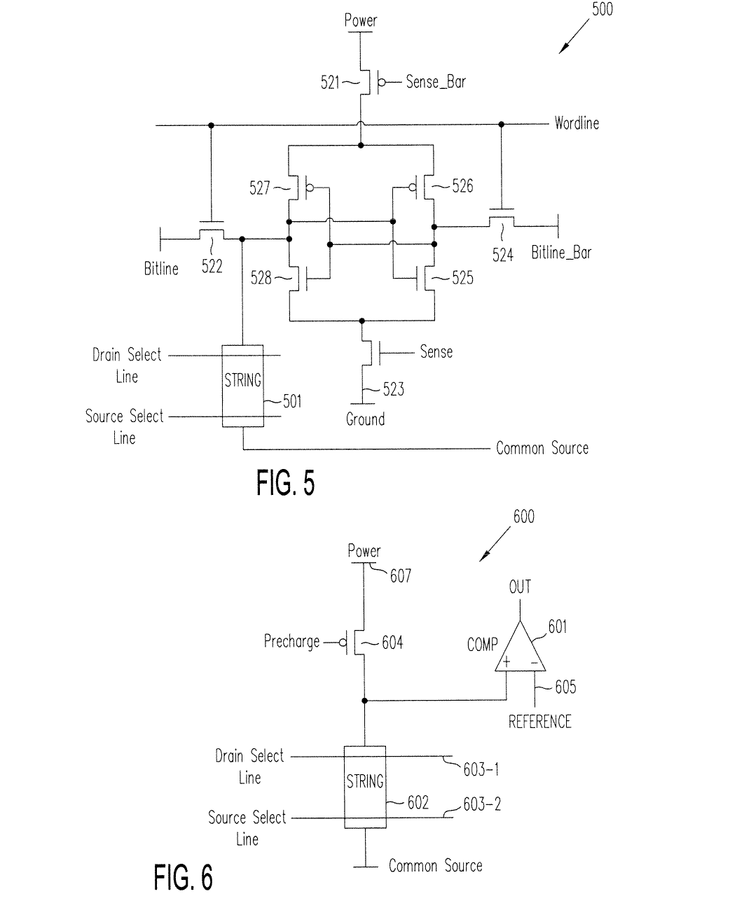

Another applicable amplifier for use in the present invention includes a conventional sense amplifier. FIG. 5 shows conventional sense amplifier 500 formed by transistors 521-528 in the mono-crystalline silicon bulk of the wafer. As shown in FIG. 5, conventional sense amplifier 500 receives the output signal of non-volatile memory string 501 on one side of a latch in sense amplifier 500. The latch is formed by transistors 525-528 as a pair of cross-coupled inverters out of transistors in the mono-crystalline bulk silicon wafer. One skilled in the art would appreciate that the configuration of FIG. 5 may be modified to receive output signals from two memory strings, based on the configurations taught in FIGS. 3 and 4 above.

Yet another applicable amplifier for use in the present invention includes a local voltage comparator. FIG. 6 shows local comparator 600, which includes precharge circuit 604 and comparator 601 formed out of transistors in the mono-crystalline bulk of the silicon wafer. The output signal of comparator 600 drives the bit line (not shown) of an associated thin-film transistor-based non-volatile memory string 602. As shown in FIG. 6, reference signal 605 may be a reference signal provided in another memory string or a reference voltage signal generated elsewhere in the integrated circuit. Precharge circuit 604 includes a PMOS transistor connecting power supply signal 607 to memory string 602, the PMOS transistor precharging the input signal to comparator 601. Precharge circuit 604 may precharge memory string 602 during programming.

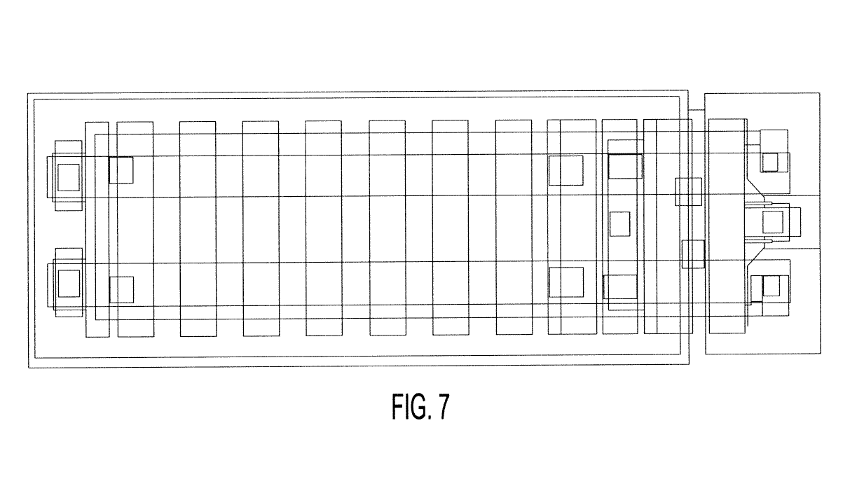

FIG. 7 is a layout of a dual-gate thin-film transistor nonvolatile string having eight word lines and two select transistors. The memory string of FIG. 7 may be configured in the manner of FIG. 3.

By combining a thin-film transistor-based nonvolatile memory string with mono-crystalline silicon transistors in the bulk local to the memory string, the low electrical current signal from the memory string may be amplified by the excellent current handling capability of the transistors in the bulk mono-crystalline silicon.

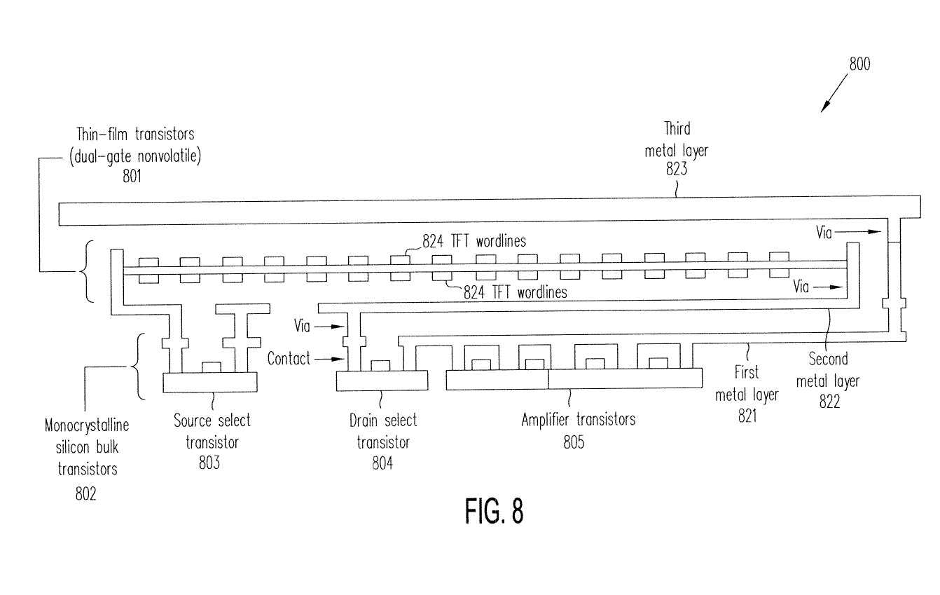

FIG. 8 illustrates in cross section dual-gate strings 801 of thin-film transistor-based nonvolatile memory array 800 integrated with mono-crystalline silicon bulk transistors 802, according to one embodiment of the present invention. As shown in FIG. 8, besides amplifiers 805, select devices 803 and 804 connected to the ends of memory string 801 are implemented in this implementation using bulk transistors as well. Alternatively, select devices 803 and 804 may be implemented as thin-film transistors at the same level as the rest of memory string 801.

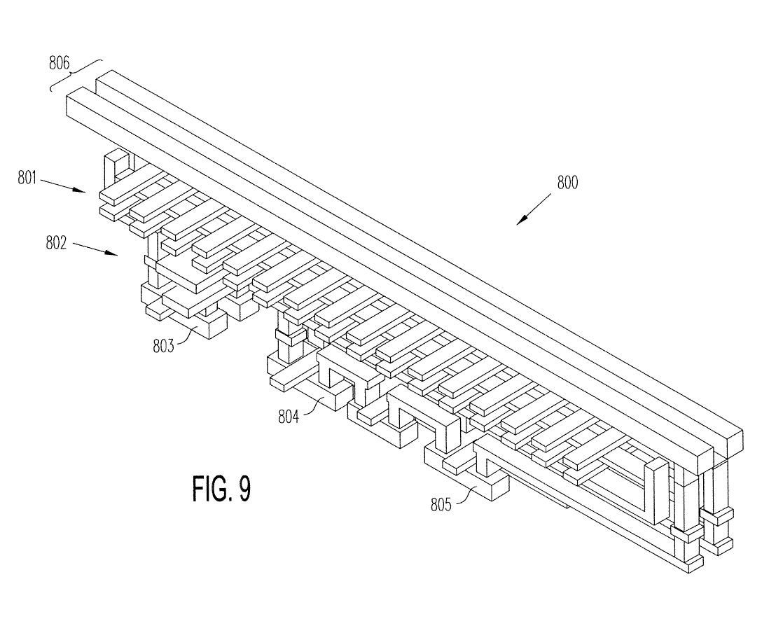

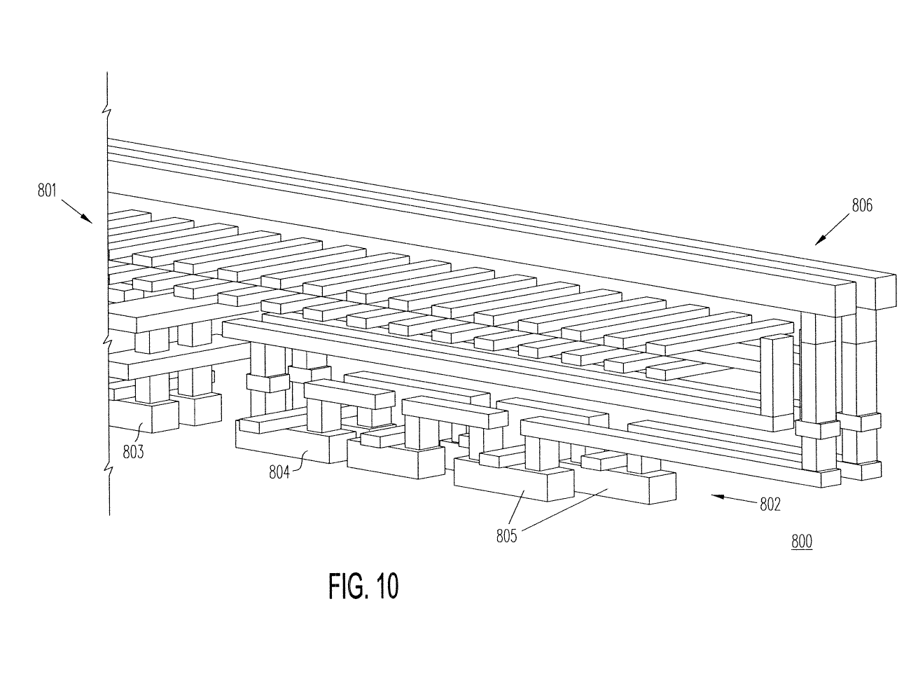

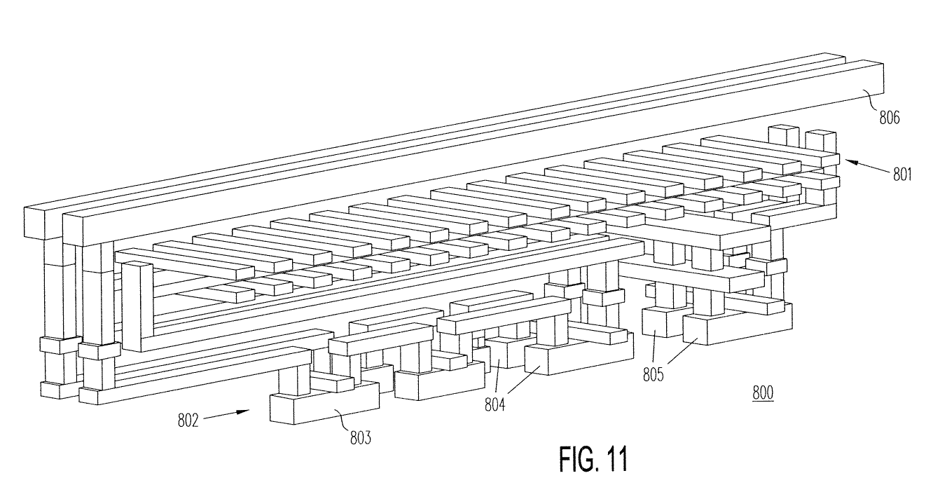

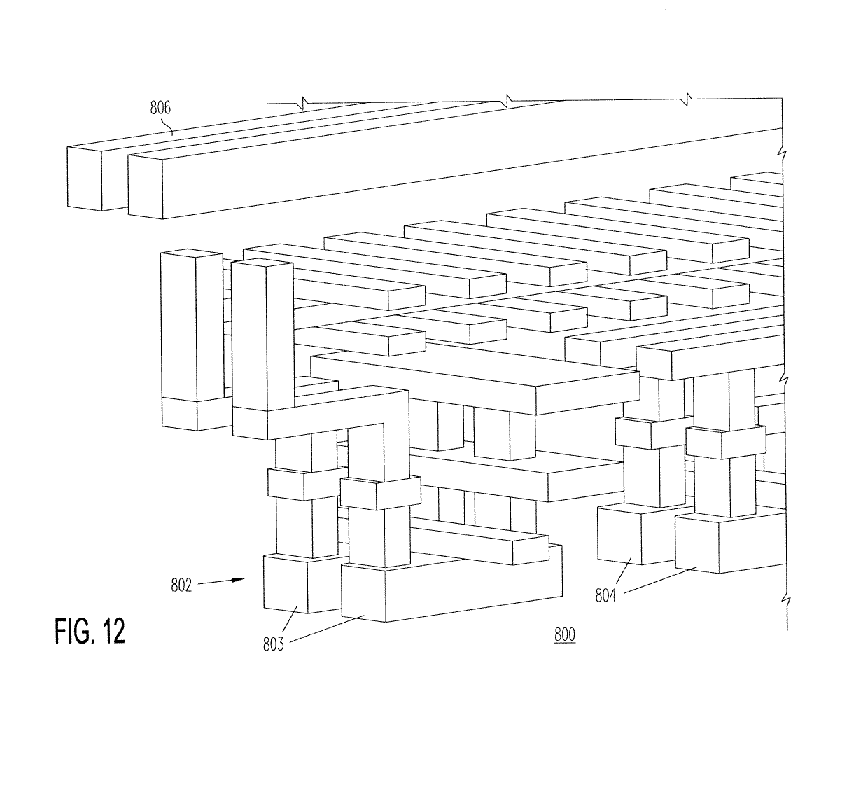

FIGS. 9-12 show various three-dimensional views of an implementation of the embodiment illustrated in FIG. 8. As shown in each of the views of FIGS. 9-12, memory strings 801 and bit lines 806 are included. FIGS. 9-12 illustrate how mono-crystalline silicon bulk transistors 802, including select devices 803 and 804 and amplifiers 805, can be located or locally associated with thin-film transistor non-volatile memory strings 801. In other implementations, bit lines 806 may be provided underneath (i.e., closer to the bulk silicon) thin-film transistors of memory strings 801.

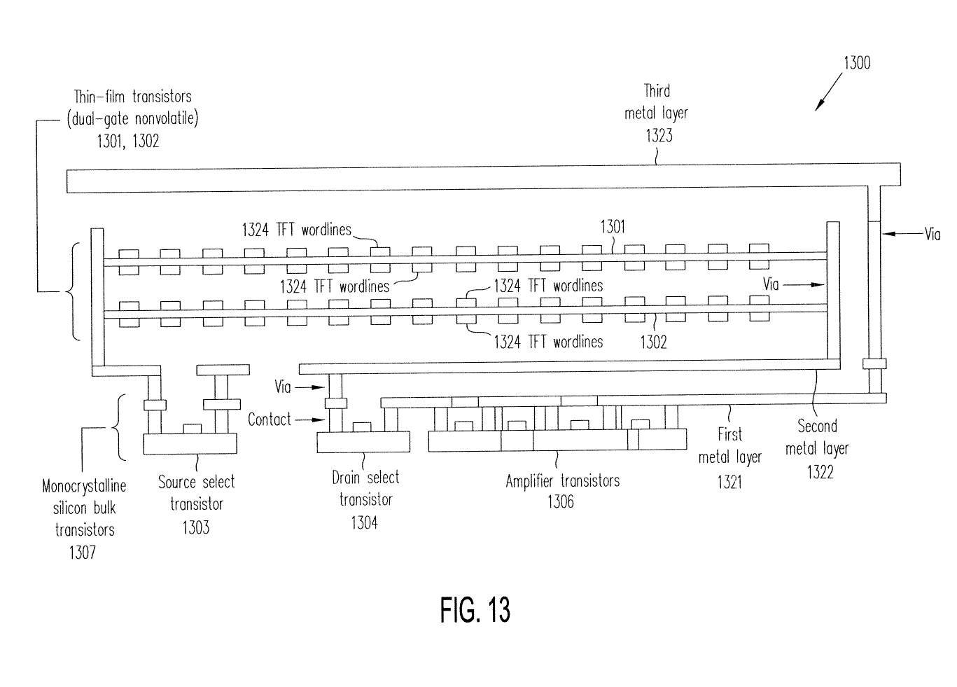

Even though—solely for illustrative purposes—memory array 800 is shown here in cross section with only two memory strings implemented in thin-film memory strings 801, memory array 800 may have any number of memory strings. Non-volatile memory array 800 may be formed and interconnected using any number of metal layers above or below the thin-film transistors of memory strings 801. (FIG. 8 shows interconnection by metal layers 821, 822 and 823 and polysilicon wordlines 824). Also, the amplifiers in mono-crystalline silicon bulk transistors 802 are not restricted to serving only one layer of thin-film transistor structures. In an implementation in which multiple memory strings are fabricated in a three-dimensional structure involving multiple layers of thin-film transistor structures, the amplifiers for all the memory strings may be fabricated in the portion of the mono-crystalline bulk silicon that is local to such a three-dimensional structure. One example of such a three-dimensional structure is provided in FIG. 13.

FIG. 13 illustrates in cross section dual-gate strings 1301 and 1302 of thin-film transistor-based nonvolatile memory array 1300, fabricated on two different thin-film structures, integrated with mono-crystalline silicon bulk transistors 1302, according to one embodiment of the present invention. As shown in FIG. 13, dual-gate thin-film transistor nonvolatile memory strings 1301 and 1302 are stacked with mono-crystalline silicon bulk transistors 1307, which select source and drain select transistors 1303 and 1304, and amplifiers 1306 that serve both memory strings 1301 and 1302. FIGS. 8 and 13 each show an implementation in which source and drain select transistors (e.g., source and drain select transistors 1303 and 1304) are also implemented in the mono-crystalline silicon bulk. (FIG. 13 shows interconnection by metal layers 1321, 1322 and 1323 and polysilicon wordlines 1324).

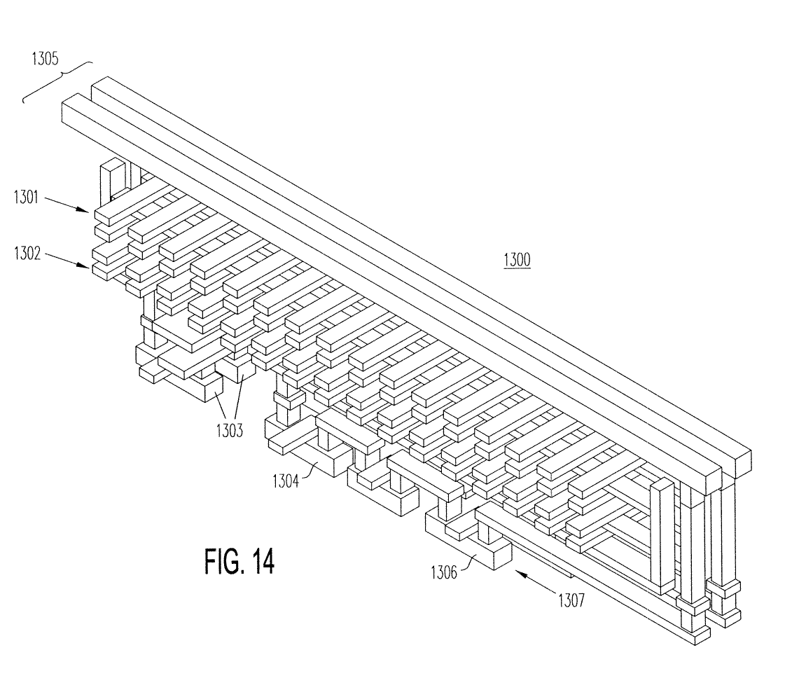

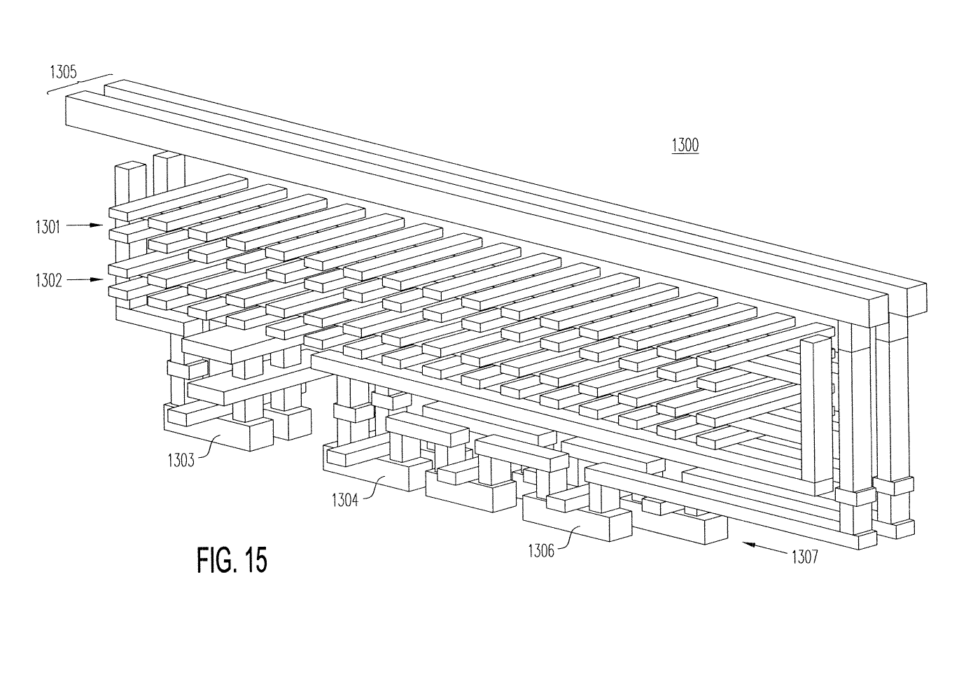

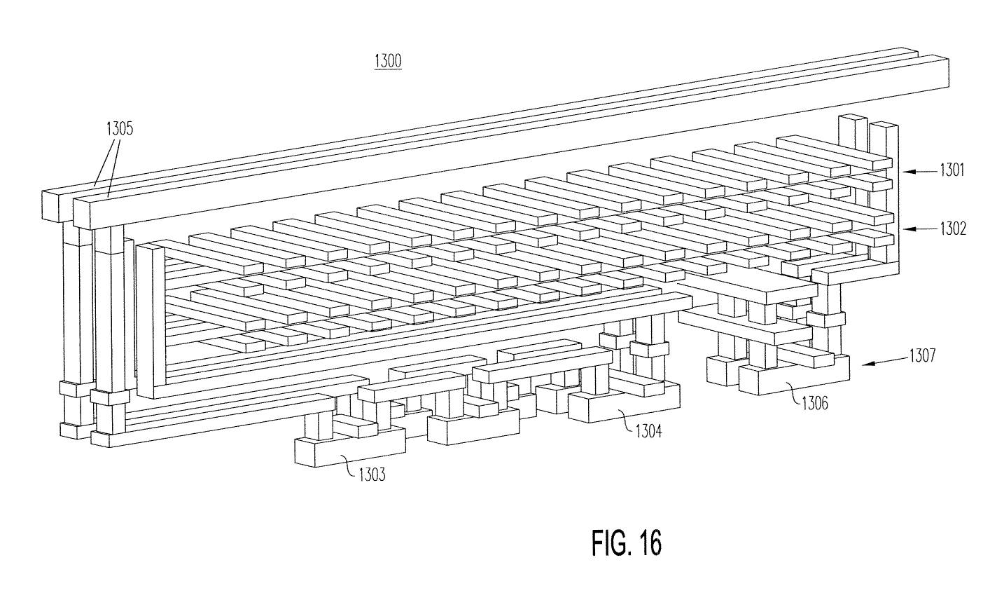

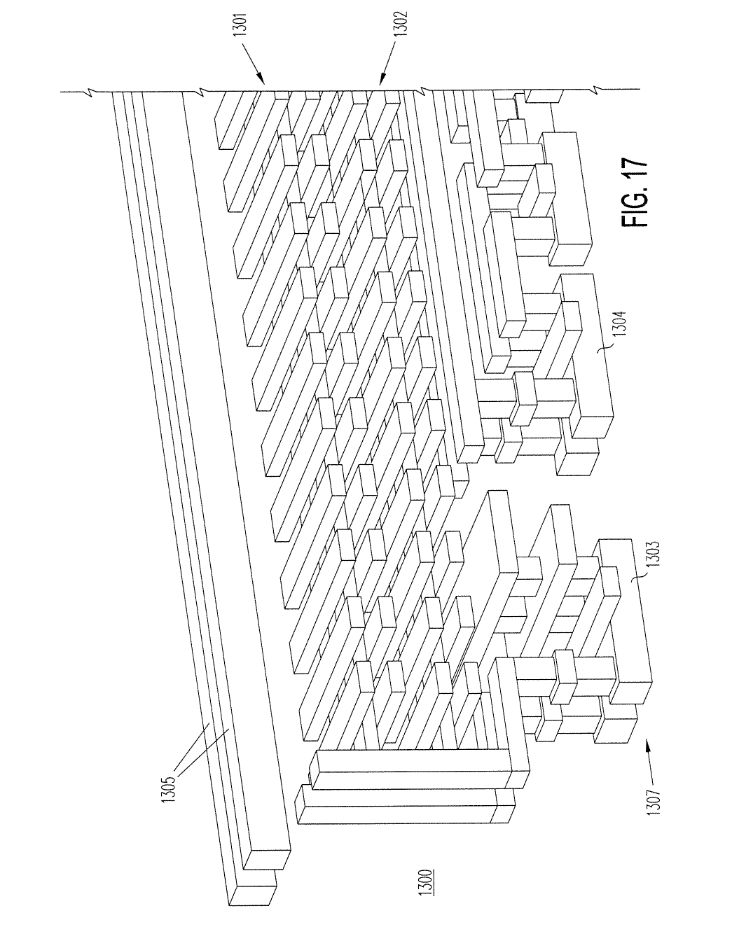

FIGS. 14-17 show various three-dimensional views of an implementation of the embodiment illustrated in FIG. 13. As shown in each of the views of FIGS. 14-17, memory strings 1301 and 1302 and bit lines 1305 are included. FIGS. 14-17 illustrate how mono-crystalline silicon bulk transistors 1307 can be located or locally associated with thin-film transistor non-volatile memory strings 1301 and 1302. In other implementations, bit lines 1307 may be provided underneath (i.e., closer to the bulk silicon) the thin-film transistors of memory strings 1301 and 1302.

The above detailed description is provided to illustrate the specific embodiments of the present invention and is not intended to be limiting. Numerous variations and modifications within the scope of the present invention are possible. The present invention is set forth in the accompanying claims.

I claim:

1. A semiconductor non-volatile memory element, comprising:
a mono-crystalline silicon substrate;
one or more thin-film layers provided over the mono-crystalline silicon substrate;
a thin-film field effect transistor fabricated in the thin-film layers having a storage gate element for storing electrical charge representing data;
one or more bit lines for providing an output signal representing the stored electrical charge; and
an output device comprising one or more transistors fabricated on the mono-crystalline silicon substrate, the output device being connected to the thin-film field effect transistor to sense the stored electrical charge and to provide the output signal.

2. The semiconductor non-volatile memory element of claim 1, wherein the transistors of the output device are separated from the thin-film field effect transistor by a distance that is less than a length of the bit lines.

3. The semiconductor non-volatile memory element of claim 1, wherein the storage gate element comprises a film that contains a nitride of silicon.

4. The semiconductor non-volatile memory element of claim 1, wherein the storage gate element comprises a floating conductor gate.

5. The semiconductor non-volatile memory element of claim 1, wherein the thin-film field effect transistor comprises a dual-gate thin-film field effect transistor.

6. The semiconductor non-volatile memory element of claim 5, wherein the dual-gate thin-film field effect transistor includes at least one floating gate conductor.

7. The semiconductor non-volatile memory element of claim 6, wherein the floating gate comprises a small-dimension thin-film conductor.

8. The semiconductor non-volatile memory element of claim 7, wherein the small-dimension thin-film conductor is less than 20 nanometers thick or on each side.

9. The semiconductor non-volatile memory element of claim 7, wherein the floating gate conductor is formed out of any of: titanium nitride (TiN), tantalum nitride (TaN), doped polysilicon, or any combination thereof.

10. The semiconductor non-volatile memory element of claim 7, wherein the floating gate conductor is formed out of nanocrystals or conductor nanodots embedded in a dielectric layer.

11. The semiconductor non-volatile memory element of claim 1, wherein the thin-film field effect transistor is one of a plurality of thin-film field effect transistors connected in the form of a first series string.

12. The semiconductor non-volatile memory element of claim 11, wherein each thin-film field effect transistor comprises a drain terminal and a source terminal, and wherein the source terminal of each thin-film field effect transistor is connected to the drain terminal of another one of the thin-film field effect transistors.

13. The semiconductor non-volatile memory element of claim 11, further comprising a second series string substantially the same as the first series string, wherein the output device selectably senses the stored electrical charge of the thin-film field effect transistors in either the first series string or the second series string.

14. The semiconductor non-volatile memory element of claim 11, wherein the thin-film field effect transistors of the first series string and the thin-film field effect transistors of the second series strings are fabricated on a different thin-film layers.

15. The semiconductor non-volatile memory element of claim 14, wherein one of the thin film layers is stacked on top of the other thin film layer.

16. The semiconductor non-volatile memory element of claim 11, wherein the output device comprises an amplifier.

17. The semiconductor non-volatile memory element of claim 11, wherein the output device comprises an SRAM cell.

18. The semiconductor non-volatile memory element of claim 11, wherein the output device comprises a sense amplifier.

19. The semiconductor non-volatile memory element of claim 11, wherein the output device comprises a reference comparator.

20. The semiconductor non-volatile memory element of claim 11, wherein the thin-film field effect transistors of the first series string are selected by one or more select devices fabricated on the mono-crystalline silicon substrate.

21. The semiconductor non-volatile memory element of claim 11, wherein the thin-film field effect transistors of the first series string are selected by one or more select devices each comprising a thin-film field effect transistor.

22. The semiconductor non-volatile memory element of claim 1, wherein the bit lines are provided on a metallic layer between the thin-film field effect transistor and the mono-crystalline silicon substrate.

23. The semiconductor non-volatile memory element of claim 1, wherein the bit lines are provided on a metallic layer above the thin-film field effect transistor.
